(19) United States
(12) Patent Application Publication
(10) Pub. No.: US 2024/0319602 A1
(43) Pub. Date: Sep. 26, 2024

(54) HARDMASK COMPOSITION, HARDMASK LAYER AND METHOD OF FORMING PATTERNS

(71) Applicant: SAMSUNG SDI CO., LTD., Yongin-si (KR)

(72) Inventors: Jooyoung CHUNG, Suwon-si (KR); Younhee Nam, Suwon-si (KR); Seulgi Jeong, Suwon-si (KR)

(21) Appl. No.: 18/599,666

(22) Filed: Mar. 8, 2024

(30) Foreign Application Priority Data
Mar. 20, 2023 (KR) 10-2023-0036111

(51) Int. Cl. G03F 7/11; C08G 8/04; C08G 10/02; G03F 7/00; G03F 7/16

(52) U.S. Cl. CPC G03F 7/11; C08G 8/04; C08G 10/02; G03F 7/0035; G03F 7/168

(57) ABSTRACT

A hardmask composition, a hardmask layer including a cured product of the hardmask composition, and a method of forming patterns using the hardmask layer including a cured product of the hardmask composition, the hardmask composition including a compound represented by Chemical Formula 1, below; and a solvent,

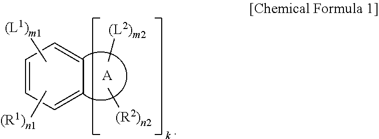

### CROSS-REFERENCE TO RELATED APPLICATION

This application claims priority to and the benefit of Korean Patent Application No. 10-2023-0036111 filed in the Korean Intellectual Property Office on Mar. 20, 2023, the entire contents of which are incorporated herein by reference.

### BACKGROUND

### 1. Field

A hardmask composition, a hardmask layer and a method of forming patterns.

### 2. Description of the Related Art

Recently, the semiconductor industry has developed to an ultra-fine technique having a pattern of, e.g., several to several tens nanometer size. Such ultrafine technique may use effective lithographic techniques. Some lithographic techniques may include providing a material layer on a semiconductor substrate; coating a photoresist layer thereon; exposing and developing the same to provide a photoresist pattern; and etching a material layer using the photoresist pattern as a mask.

### SUMMARY

The embodiments may be realized by providing a hardmask composition including a compound represented by Chemical Formula 1; and a solvent,

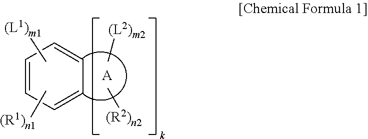

wherein, in Chemical Formula 1, A is a 5-membered or 6-membered ring formed through a saturated or unsaturated bond, wherein a skeleton of the ring consists entirely of substituted or unsubstituted carbon atoms, or has at least one carbon atom replaced by an oxygen atom or a nitrogen atom, L¹ and L² are each independently —(C═O)H, R¹ and R² are each independently deuterium, a halogen atom, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 heteroalkyl group, or a substituted or unsubstituted C1 to C30 heterocycloalkyl group, m1 and m2 are each independently 0 or 1, and m1+m2=1, n1 is an integer of 0 to 3, n2 is 0 or 1, k is 0 or 1, if k=0, m1=1.

In Chemical Formula 1, R¹ and R² in Chemical Formula 1 may each independently be deuterium, a halogen atom, a hydroxy group, a substituted or unsubstituted C1 to C20 alkoxy group, a substituted or unsubstituted C1 to C20 alkyl group, a substituted or unsubstituted C2 to C20 alkenyl group, or a substituted or unsubstituted C2 to C20 alkynyl group, n1+n2 may be an integer from 1 to 4.

In Chemical Formula 1, R¹ and R² in Chemical Formula 1 may each independently be deuterium, a halogen atom, a hydroxy group, a substituted or unsubstituted C1 to C10 alkoxy group, or a substituted or unsubstituted C1 to C10 alkyl group, and n1 may be an integer of 1 to 3.

The compound represented by Chemical Formula 1 may be represented by one of Chemical Formula 2 to Chemical Formula 5:

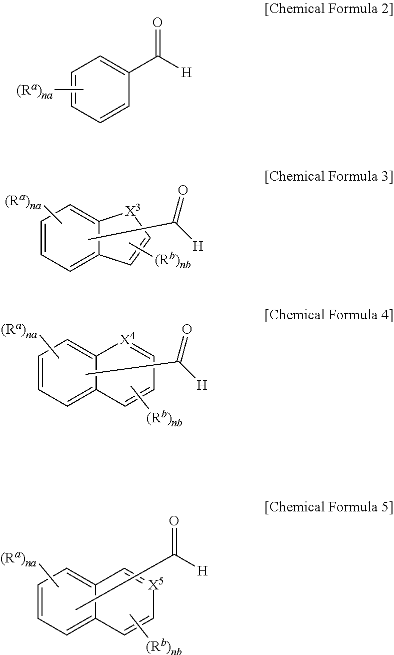

in Chemical Formula 2 to Chemical Formula 5, R^{a} and R^{b} may each independently be deuterium, a halogen atom, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 heteroalkyl group, or a substituted or unsubstituted C1 to C30 heterocycloalkyl group, X³ may be —CR^{c}R^{d}—, —O—, or —NR^{e}—, X⁴ and X⁵ may each independently be —CR^{f}—, or —N—, R^{e} to R^{f} may each independently be hydrogen, deuterium, a substituted or unsubstituted C1 to C20 alkyl group, or a substituted or unsubstituted C6 to C20 aryl group, na may be an integer of 0 to 3, and nb may be 0 or 1.

In Chemical Formulas 2 to 5, R^{a} and R^{b} may each independently be deuterium, a halogen atom, a hydroxy group, a substituted or unsubstituted C1 to C20 alkoxy group, a substituted or unsubstituted C1 to C20 alkyl group, a substituted or unsubstituted C2 to C20 alkenyl group, or a substituted or unsubstituted C2 to C20 alkynyl group, and na+nb may be an integer of 1 to 4.

In Chemical Formulas 2 to 5, R^{a} and R^{b} may each independently be, deuterium, a halogen atom, a hydroxy group, a substituted or unsubstituted C1 to C10 alkoxy group, or a substituted or unsubstituted C1 to C10 alkyl group, and na may be an integer of 1 to 3.

In Chemical Formula 3, X³ may be —O—, or —NR^{e}—, in Chemical Formula 4, X⁴ and Chemical Formula 5, X⁴ may each independently be —CR^{f}—, and R^{e} and R^{f} are each independently hydrogen, deuterium, or a substituted or unsubstituted C1 to C10 alkyl group.

The self-polymer may have a weight average molecular weight of about 1,000 g/mol to about 200,000 g/mol.

The self-polymer may be included in an amount of about 0.1 wt % to about 30 wt % based on a total weight of the hardmask composition.

The solvent may include propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

The embodiments may be realized by providing a hardmask layer including a cured product of the hardmask composition according to an embodiment.

The embodiments may be realized by providing a method of forming patterns, the method including providing a material layer on a substrate, applying the hardmask composition according to an embodiment on the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a portion of the material layer, and etching an exposed part of the material layer.

Forming the hardmask layer may include heat-treating at about 100° C. to about 1,000° C.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, C9 to C30 allylaryl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof. As used herein, hydrogen substitution (—H) may include deuterium substitution (-D) or tritium substitution (-T). For example, any hydrogen in any compound described herein may be protium, deuterium, or tritium (e.g., based on natural or artificial substitution). As used herein, the term “or” is not necessarily an exclusive term, e.g., “A or B” would include A, B, or A and B.

In addition, adjacent two substituents of the substituted halogen atom (F, Br, Cl, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring.

As used herein, when a definition is not otherwise provided, “aryl group” refers to a group including at least one hydrocarbon aromatic moiety, and includes hydrocarbon aromatic moieties linked by a single bond and hydrocarbon aromatic moieties fused directly or indirectly to provide a non-aromatic fused ring. The aryl group may include a monocyclic, polycyclic or fused polycyclic (i.e., rings sharing adjacent pairs of carbon atoms) functional group.

More specifically, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted triphenylene group, a substituted or unsubstituted perylenyl group, a substituted or unsubstituted fluorenyl group, a substituted or unsubstituted indenyl group, a substituted or unsubstituted furanyl group, or a combination thereof.

As used herein, when a definition is not otherwise provided, “hetero” refers to one including 1 to 3 heteroatoms selected from N, O, S, Se, and P.

As used herein, when a definition is not otherwise provided, “alkyl group” refers to a monovalent linear or branched hydrocarbon group formed by linking carbon to carbon with a single bond.

As used herein, when a definition is not otherwise provided, “alkenyl group” refers to a monovalent linear or branched hydrocarbon group containing at least one double bond between carbons.

As used herein, when a definition is not otherwise provided, “alkynyl group” refers to a monovalent linear or branched hydrocarbon group containing at least one triple bond between carbons.

As used herein, when a definition is not otherwise provided, “cycloalkyl group” refers to a monovalent cyclic hydrocarbon group formed by linking carbon to carbon with a single bond.

As used herein, when a definition is not otherwise provided, “heteroalkyl group” refers to a monovalent linear or branched hydrocarbon group including a single bond between carbons, wherein at least one carbon is substituted with any one of the heteroatoms N, O, S, Se, and P.

As used herein, when a definition is not otherwise provided, “heterocycloalkyl group” refers to a monovalent cyclic hydrocarbon group including a single bond between carbons, wherein at least one carbon is substituted with any one of the heteroatoms N, O, S, Se, and P.

As used herein, the polymer may include both an oligomer and a polymer.

Unless otherwise specified in the present specification, the “weight average molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

The hardmask composition according to some embodiments may include a self-polymer, and since the structural units of the self-polymer may be densely linked, if a composition including the same is heat-treated, a dense film structure may be formed by dense connections between polymers or structural units. Accordingly, a hardmask layer formed from the hardmask composition according to some embodiments may have a high film density and improved film strength.

The hardmask composition according to some embodiments may include, e.g., a self-polymer of a compound represented by Chemical Formula 1, and a solvent:

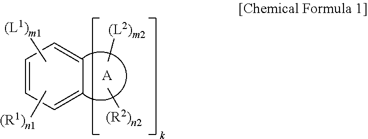

In Chemical Formula 1, A may be or include, e.g., a 5-membered or 6-membered ring formed through a saturated or unsaturated bond. In an implementation, a skeleton of the ring may consist entirely of substituted or unsubstituted carbon atoms, or may have at least one carbon atom replaced by an oxygen atom or a nitrogen atom.

L¹ and L² may each independently be, e.g., —(C═O)H.

R¹ and R² may each independently be or include, e.g., deuterium, a halogen atom, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 heteroalkyl group, or a substituted or unsubstituted C1 to C30 heterocycloalkyl group.

m1 and m2 may each independently be, e.g., 0 or 1, and m1+m2=1.

n1 may be, e.g., an integer of 0 to 3. n2 may be, e.g., 0 or 1.

k may be, e.g., 0 or 1.

In an implementation, if k=0, m1=1.

The compound represented by Chemical Formula 1 may include an aromatic ring or hetero ring with a high carbon content, so that the film of the hardmask layer including the self-polymer of the compound may be hardened. In addition, the compound may include relatively small aromatic rings or hetero rings, so that they may be more densely connected to each other, to increase the film density of the hardmask layer including the self-polymer, and to further increase film strength.

The self-polymer according to some embodiments may be formed by self-polymerization of the compound represented by Chemical Formula 1. The compounds may be linked by an aldehyde group contained in the compound, and the linkage may occur randomly. In an implementation, a carbon of an aldehyde in one molecule may be bonded to a random carbon of another molecule, and therefore, the bond may occur randomly. That is, the self-polymer according to some embodiments may have a form in which the compound represented by Chemical Formula 1 may be randomly branched and linked. The initial reaction in which bonds between compounds may occur randomly can be simply schematized as Reaction Scheme 1. However, Reaction Scheme 1 is only an example of a bonding reaction between compounds.

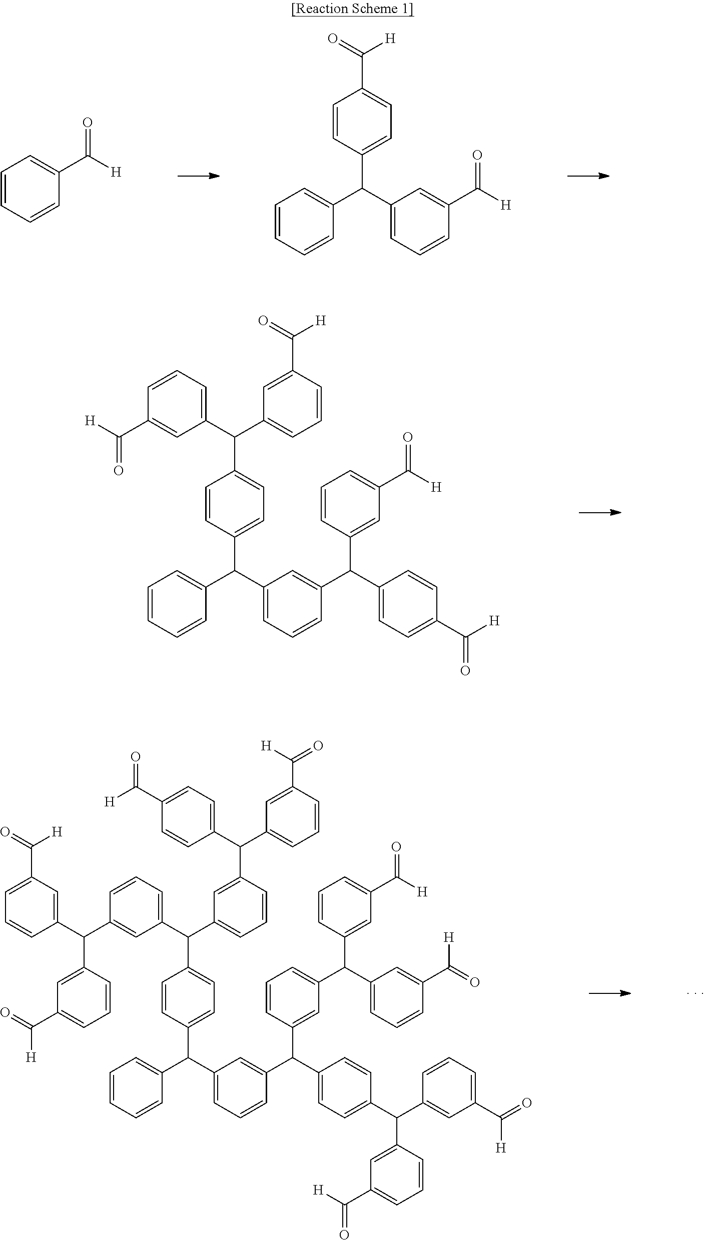 [SMILES: O=Cc1ccccc1 ; O=Cc1ccc(C(c2ccccc2)c2cccc(C=O)c2)cc1 ; O=Cc1ccc(C(c2cccc(C=O)c2)c2cccc(C(c3ccccc3)c3ccc(C(c4cccc(C=O)c4)c4cccc(C=O)c4)cc3)c2)cc1 ; O=Cc1ccc(C(c2cccc(C=O)c2)c2cccc(C(c3ccc(C(c4ccccc4)c4cccc(C(c5ccc(C(c6cccc(C=O)c6)c6cccc(C=O)c6)cc5)c5cccc(C(c6cccc(C=O)c6)c6cccc(C=O)c6)c5)c4)cc3)c3cccc(C(c4cccc(C=O)c4)c4cccc(C=O)c4)c3)c2)cc1]

As shown in Reaction Scheme 1, if a compound is subjected to self-polymerization, the linkage between structural units may be more dense than a polymer formed by linking two or more structural units together. Accordingly, the film strength of a hardmask layer formed from a composition containing a self-polymer of the compound represented by Chemical Formula 1 may be further improved.

A in Chemical Formula 1 may be, e.g., a 5-membered or 6-membered ring formed through a saturated or unsaturated bond, that is, a single bond or a double bond, and the skeleton of the ring may consist of all substituted or unsubstituted carbon atoms, or one or more of the carbon atoms may be replaced by an oxygen atom or a nitrogen atom. The number of elements forming the ring of A may be, e.g., 5 or 6. If there are five elements forming the ring of A, one of the elements may be oxygen (O) or nitrogen (N), and accordingly, A may be furan or pyrrole.

R¹ and R² in Chemical Formula 1 may each independently be, e.g., deuterium, a halogen atom, a hydroxy group, a substituted or unsubstituted C1 to C20 alkoxy group, a substituted or unsubstituted C1 to C20 alkyl group, a substituted or unsubstituted C2 to C20 alkenyl group, or a substituted or unsubstituted C2 to C20 alkynyl group. In an implementation, R¹ and R² in Chemical Formula 1 may each independently be, e.g., deuterium, a halogen atom, a hydroxy group, a substituted or unsubstituted C1 to C10 alkoxy group, or a substituted or unsubstituted C1 to C10 alkyl group. In an implementation R¹ and R² in Chemical Formula 1 may each independently be a hydroxy group, a substituted or unsubstituted C1 to C5 alkoxy group, or a substituted or unsubstituted C1 to C5.

In embodiments, n1+n2 in Chemical Formula 1 may be an integer of 0 to 4, e.g., an integer of 1 to 4 or an integer of 1 to 3. In embodiments, n1 may be an integer from 0 to 3, e.g., an integer from 1 to 3.

In embodiments, m1 and m2 in Chemical Formula 1 may each independently be, e.g., 0 or 1, but m1 and m2 may not both be 0, and m1+m2=1.

The compound represented by Chemical Formula 1 may be represented by, e.g., one of Chemical Formula 2 to Chemical Formula 5.

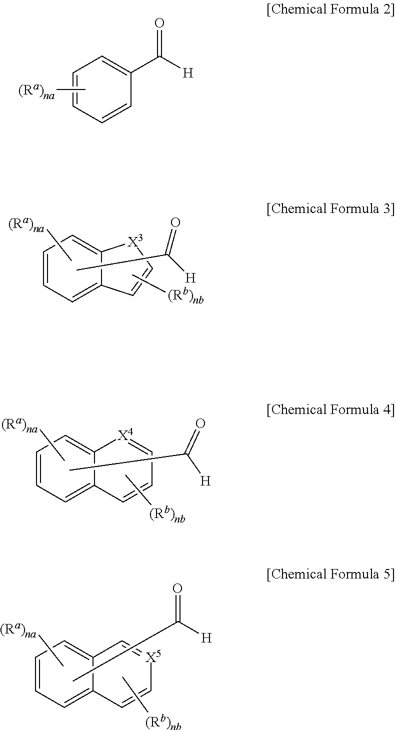

In Chemical Formula 2 to Chemical Formula 5, R^{a} and R^{b} may each independently be, e.g., deuterium, a halogen atom, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 heteroalkyl group, or a substituted or unsubstituted C1 to C30 heterocycloalkyl group.

In an implementation, R^{a} and R^{b} may each independently be, e.g., deuterium, a halogen atom, a hydroxy group, a substituted or unsubstituted C1 to C20 alkoxy group, a substituted or unsubstituted C1 to C20 alkyl group, a substituted or unsubstituted C2 to C20 alkenyl group, or a substituted or unsubstituted C2 to C20 alkynyl group, for example independently, deuterium, a halogen atom, a hydroxy group, a substituted or unsubstituted C1 to C10 alkoxy group, or a substituted or unsubstituted C1 to C10 alkyl group.

In an implementation, R^{a} and R^{b} may each independently be, e.g., a hydroxy group, a substituted or unsubstituted C1 to C5 alkoxy group, or a substituted or unsubstituted C1 to C5 alkyl group. In an implementation, R^{a} and R^{b} may each independently be, e.g., a hydroxy group, a substituted or unsubstituted C1 to C5 alkoxy group, or a substituted C1 to C5 alkyl group.

X³ may be, e.g., —CR^{c}R^{d}—, —O—, or —NR^{e}—, wherein X⁴ and X⁵ may each independently be, e.g., —CR^{f}—, or —N—, and R^{e} to R^{f} may each independently be, e.g., hydrogen, deuterium, a substituted or unsubstituted C1 to C20 alkyl group, or a substituted or unsubstituted C6 to C20 aryl group. In an implementation, R^{e} to R^{f} may each independently be, e.g., hydrogen, deuterium, a substituted or unsubstituted C1 to C10 alkyl group, or a substituted or unsubstituted C6 to C16 aryl group. In an implementation, R^{c} to R^{f} may each independently be, e.g., hydrogen, deuterium, or a substituted or unsubstituted C1 to C10 alkyl group.

In an implementation, in Chemical Formula 3, X³ may be, e.g., —CR^{c}R^{d}—, —O—, or —NR^{e}-(wherein, R^{e} may be, e.g., hydrogen, deuterium, or a substituted or unsubstituted C1 to C10 alkyl group), —CH₂—, —CH(CH₃)—, —O—, or —NH—, or —O—, or —NH—.

In an implementation, X⁴ in Chemical Formula 4 and X⁵ in Chemical Formula 5 may each independently be, e.g., —CR^{f}—, wherein R^{f} may be, e.g., hydrogen, deuterium, or a substituted or unsubstituted C1 to C10 alkyl group.

In Chemical Formula 2 to Chemical Formula 5, na may be, e.g., an integer from 0 to 3 or an integer from 1 to 3. Additionally, nb in Chemical Formula 3 to Chemical Formula 5 may be, e.g., 0 or 1.

The self-polymer may have, e.g., a weight average molecular weight of about 1,000 g/mol to about 200,000 g/mol. In an implementation, the self-polymer may have, e.g., a weight average molecular weight of about 1,000 g/mol to about 150,000 g/mol, about 1,000 g/mol to about 100,000 g/mol, about 1,200 g/mol to about 50,000 g/mol, or about 1,200 g/mol to about 10,000 g/mol. By having a weight average molecular weight within the above ranges, the carbon content and solubility in the solvent of the hardmask composition including the above polymer may be adjusted and optimized.

The self-polymer may be included, e.g., in an amount of about 0.1 wt % to about 30 wt % based on a total weight of the hardmask composition. In an implementation, the self-polymer may be included, e.g., in an amount of about 0.2 wt % to about 30 wt %, about 0.5 wt % to about 30 wt %, about 1 wt % to about 30 wt %, about 1.5 wt % to about 25 wt %, or about 2 wt % to about 20 wt %. By including the self-polymer within the above range, a thickness, a surface roughness, and a planarization degree of the hardmask may be easily adjusted.

The hardmask composition according to some embodiments may include a solvent. In an implementation, the solvent may include, e.g., propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. In an implementation, solvent may be a suitable solvent that has sufficient solubility and/or dispersibility for the self-polymer.

In an implementation, the hardmask composition may further include an additive, e.g., a surfactant, a crosslinking agent, a thermal acid generator, or a plasticizer.

The surfactant may include, e.g., a fluoroalkyl-based compound, alkylbenzenesulfonate, alkylpyridinium salt, polyethylene glycol, a quaternary ammonium salt, or the like.

The crosslinking agent may include, e.g., a melamine, a substituted urea, or a polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In addition, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

The thermal acid generator may include, e.g., an acid compound such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid, or 2,4,4,6-tetrabromocyclohexadienone, benzointosylate, 2-nitrobenzyltosylate, or other organic sulfonic acid alkyl esters.

In an implementation, a hardmask layer including a cured product of the aforementioned hardmask composition may be provided.

Hereinafter, a method of forming patterns using the aforementioned hardmask composition is described.

A method of forming patterns according to some embodiments may include providing a material layer on a substrate, applying a hardmask composition including the aforementioned polymer and solvent on the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may be, e.g., silicon wafer, a glass substrate, or a polymer substrate. The material layer may be a material to be finally patterned, e.g., a metal layer such as an aluminum layer or a copper layer, a semiconductor layer such as a silicon layer, or an insulation layer such as a silicon oxide layer and a silicon nitride layer. The material layer may be formed through a method such as a chemical vapor deposition (CVD) process.

The hardmask composition may be the same as described above, and may be applied by spin-on coating in a form of a solution. In an implementation, an application thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process, and a second heat-treating process.

In an implementation, the heat-treating of the hardmask composition may include, e.g., one heat-treating process performed at about 100° C. to about 600° C. for about 10 seconds to about 1 hour. In an implementation the heat-treating may be performed under an atmosphere of air or nitrogen, or an atmosphere having oxygen concentration of about 1 wt % or less.

In an implementation, the heat-treating of the hardmask composition may include, e.g., a first heat-treating process performed at about 100° C. to about 1,000° C., about 100° C. to about 800° C., about 100° C. to about 500° C., or about 150° C. to about 400° C. for about 30 seconds to about 1 hour, about 30 seconds to about 30 minutes, about 30 seconds to about 10 minutes, or about 30 seconds to about 5 minutes.

In an implementation, the heat-treating may include, e.g., a second heat-treating process that may be consecutively performed at about 100° C. to about 1,000° C., about 300° C. to about 1,000° C., about 500° C. to about 1,000° C., or about 500° C. to about 600° C. for about 30 seconds to about 1 hour, about 30 seconds to about 30 minutes, about 30 seconds to about 10 minutes, about 30 seconds to 5 minutes. In an implementation, the first and second heat-treating processes may be performed under an air or nitrogen atmosphere, or may be performed under an atmosphere with an oxygen concentration of about 1 wt % or less.

By performing at least one of the steps of heat-treating the hardmask composition at a high temperature of 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include a first heat-treating process, a second heat-treating process, a UV/Vis curing process, and a near IR curing process, or may include two or more processes consecutively.

In an implementation, the method may further include forming a silicon-containing thin layer on the hardmask layer. The silicon-containing thin layer may be formed of, e.g., SiCN, SiOC, SiON, SiOCN, SiC, SiO, or SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas and the etching gas may include, e.g., N₂/O₂, CHF₃, CF₄, Cl₂, BCl₃, or a mixed gas thereof.

The etched material layer may be formed in a plurality of patterns, and the plurality of patterns may include a metal pattern, a semiconductor pattern, an insulation pattern, or the like, e.g., diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Self-Polymer

### Synthesis Example 1

In a 1 L 3-neck flask, 122 g of 4-hydroxybenzaldehyde and 19 g of p-toluene sulfonic acid monohydrate were dissolved in 200 g of propylene glycol monomethyl ether acetate (PGMEA) to prepare a solution, and the solution was stirred at 90° C. to 100° C. for 40 hours to perform a reaction. When the polymerization reaction was completed, an intermediate product therefrom was slowly cooled at ambient temperature. The intermediate product was added to 400 g of distilled water and 400 g of methanol and then, vigorously stirred and allowed to stand. Subsequently, after removing a supernatant, precipitates therefrom were dissolved in 200 g of PGMEA to obtain Self-polymer A. (Mw: 1,500 g/mol)

### Synthesis Example 2

174 g of 4-trifluoromethylbenzaldehyde and 19 g of p-toluene sulfonic acid monohydrate were dissolved in 200 g of PGMEA in a 1 L 3-neck flask to prepare a solution, and the solution was stirred in a thermostat at 90° C. to 100° C. to perform a reaction for 10 hours. When the polymerization reaction was completed, an intermediate product therefrom was slowly cooled at ambient temperature. The intermediate product was added to 400 g of distilled water and 400 g of methanol and then, vigorously stirred and allowed to stand. Subsequently, after removing a supernatant, precipitates therefrom were dissolved in 200 g of PGMEA to obtain Self-polymer B. (Mw: 2,000 g/mol)

### Synthesis Example 3

138 g of 3,4-dihydroxybenzaldehyde and 19 g of p-toluene sulfonic acid monohydrate were dissolved in 200 g of PGMEA in a 1 L 3-neck flask to prepare a solution, and the solution was stirred at 90° C. to 100° C. to perform a reaction for 20 hours. When the polymerization reaction was completed, an intermediate product therefrom was slowly cooled at ambient temperature. The intermediate product was added to 400 g of distilled water and 400 g of methanol and then, vigorously stirred and allowed to stand. Subsequently, after removing a supernatant, precipitates therefrom were dissolved in 200 g of PGMEA to obtain Self-polymer C. (Mw: 1,500 g/mol)

### Comparative Synthesis Example

160 g of 1-naphthol, 30 g (0.2 mol) of paraformaldehyde, and 19 g of p-toluene sulfonic acid monohydrate were dissolved in 200 g of PGMEA in a 1 L 3-neck flask and then, stirred at 90° C. to 100° C. to perform a reaction for 5 hours. When a polymerization reaction was completed, an intermediate product therefrom was slowly cooled at ambient temperature. The intermediate product was added to 400 g of distilled water and 400 g of methanol and then, vigorously stirred and allowed to stand. Subsequently, after removing a supernatant, precipitates therefrom were dissolved in 200 g of PGMEA to obtain a comparative polymer. (Mw: 2,000 g/mol)

Examples and Comparative Examples: Preparation of Hardmask Composition

### Example 1

A hardmask composition was prepared by stirring 5 g of Self-polymer A according to Synthesis Example 1 and 50 g of a mixture of cyclohexanone/PGMEA (a volume ratio of 1:1) for 60 minutes and then, filtering the solution with a 0.45 m TEFLON (tetrafluoroethylene) filter.

### Example 2

A hardmask composition was prepared in the same manner as in Example 1 except that Self-polymer B was used instead of Self-polymer A.

### Example 3

A hardmask composition was prepared in the same manner as in Example 1 except that Self-polymer C was used instead of Self-polymer A.

### Comparative Example

A hardmask composition was prepared in the same manner as in Example 1 except that the comparative polymer was used instead of Self-polymer A.

### Evaluation 1: Film Density Evaluation

Each of the hardmask compositions according to Examples 1 to 3 and the Comparative Example was spin-coated on a silicon wafer and then, heat-treated on a hot plate at about 400° C. for about 2 minutes to form a about 1,000 Å-thick hardmask layer. The hardmask layer was measured with respect to film density by using an X-ray diffraction equipment (Malvern PANalytical Ltd.). The results are shown in Table 1.

TABLE 1

| | Film density (g/cm³) |
|---|---|
| Example 1 | 1.44 |
| Example 2 | 1.44 |
| Example 3 | 1.50 |
| Comparative Example | 1.35 |

Referring to Table 1, the hardmask layers formed of the hardmask compositions of Examples 1 to 3 exhibited excellent film density, compared with the hardmask layer formed of the hardmask composition of the Comparative Example.

### Evaluation 2: Film Strength Evaluation

Each of the hardmask compositions of Examples 1 to 3 and the Comparative Example was coated to be 5,000 Å thick on a silicon wafer and then, heat-treated on a hot plate at 400° C. for 2 minutes to form a thin film. Subsequently, the thin film was measured with respect to hardness (H) and a modulus (E) by using a nanoindenter (a cube corner tip, Pmax=300 μN). The results are shown in Table 2.

TABLE 2

| | Hardness (H) | Modulus (E) |
|---|---|---|
| Example 1 | 0.65 | 8.9 |
| Example 2 | 0.64 | 9.1 |
| Example 3 | 0.72 | 9.8 |
| Comparative Example | 0.45 | 7.5 |

Referring to Table 2, the hardmasks formed of the hardmask compositions of Examples 1 to 3 exhibited much higher hardness and modulus than the hardmask formed of the hardmask composition of the Comparative Example. In other words, the hardmasks formed of the hardmask compositions of the Examples, compared with the hardmask formed of the hardmask composition of the Comparative Example, exhibited excellent film strength to provide hardmasks with excellent mechanical properties.

By way of summation and review, according to small-sizing the pattern to be formed, it may be difficult to provide a fine pattern having an excellent profile by only some typical lithographic techniques. Accordingly, an auxiliary layer, called a hardmask layer, may be formed between the material layer and the photoresist layer to provide a fine pattern.

This hardmask layer may serve as an interlayer that transfers a fine pattern of the photoresist through selective etching. Therefore, the hard mask layer may require high film density and improved film strength to withstand the etching process required for pattern transfer.

One or more embodiments may provide a hardmask composition that may be effectively applied to a hardmask layer.

One or more embodiments may provide a hardmask layer including a cured product of the hardmask composition.

One or more embodiments may provide a method of forming patterns using the hardmask composition.

The hardmask composition according to some embodiments may have excellent crosslinking characteristics, and the hardmask layer formed therefrom may have excellent film strength and improved film density, thereby ensuring excellent pattern formation.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a self-polymer of a compound represented by Chemical Formula 1; and
a solvent, 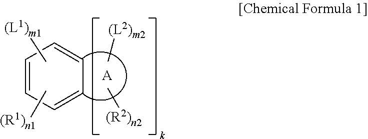
wherein, in Chemical Formula 1,
A is a 5-membered or 6-membered ring formed through a saturated or unsaturated bond, wherein a skeleton of the ring consists entirely of substituted or unsubstituted carbon atoms, or has at least one carbon atom replaced by an oxygen atom or a nitrogen atom,
L¹ and L² are each independently —(C═O)H,
R¹ and R² are each independently deuterium, a halogen atom, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 heteroalkyl group, or a substituted or unsubstituted C1 to C30 heterocycloalkyl group,
m1 and m2 are each independently 0 or 1, and m1+m2=1,
n1 is an integer of 0 to 3, n2 is 0 or 1,
k is 0 or 1, and
if k=0, m1=1.

2. The hardmask composition as claimed in claim 1, wherein:
R¹ and R² of Chemical Formula 1 are each independently deuterium, a halogen atom, a hydroxy group, a substituted or unsubstituted C1 to C20 alkoxy group, a substituted or unsubstituted C1 to C20 alkyl group, a substituted or unsubstituted C2 to C20 alkenyl group, or a substituted or unsubstituted C2 to C20 alkynyl group, and
n1+n2 is an integer of 1 to 4.

3. The hardmask composition as claimed in claim 1, wherein:
R¹ and R² of Chemical Formula 1 are each independently deuterium, a halogen atom, a hydroxy group, a substituted or unsubstituted C1 to C10 alkoxy group, or a substituted or unsubstituted C1 to C10 alkyl group, and
n1 is an integer of 1 to 3.

4. The hardmask composition as claimed in claim 1, wherein:
the compound represented by Chemical Formula 1 is represented by one of Chemical Formula 2 to Chemical Formula 5: 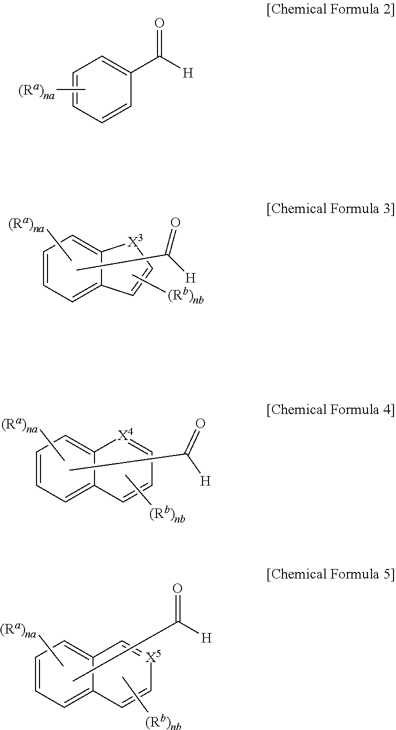
in Chemical Formula 2 to Chemical Formula 5,
R^{a} and R^{b} are each independently deuterium, a halogen atom, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 heteroalkyl group, or a substituted or unsubstituted C1 to C30 heterocycloalkyl group,
X³ is —CR^{c}R^{d}—, —O—, or —NR^{e}—,
X⁴ and X⁵ are each independently —CR^{f}— or —N—,
R^{c} to R^{f} are each independently hydrogen, deuterium, a substituted or unsubstituted C1 to C20 alkyl group, or a substituted or unsubstituted C6 to C20 aryl group,
na is an integer of 0 to 3, and
nb is 0 or 1.

5. The hardmask composition as claimed in claim 4, wherein in Chemical Formula 2 to Chemical Formula 5,
R^{a} and R^{b} are each independently deuterium, a halogen atom, a hydroxy group, a substituted or unsubstituted C1 to C20 alkoxy group, a substituted or unsubstituted C1 to C20 alkyl group, a substituted or unsubstituted C2 to C20 alkenyl group, or a substituted or unsubstituted C2 to C20 alkynyl group, and
na+nb is an integer of 1 to 4.

6. The hardmask composition as claimed in claim 4, wherein in Chemical Formula 2 to Chemical Formula 5,
R^{a} and R^{b} are each independently deuterium, a halogen atom, a hydroxy group, a substituted or unsubstituted C1 to C10 alkoxy group, or a substituted or unsubstituted C1 to C10 alkyl group, and
na is an integer of 1 to 3.

7. The hardmask composition as claimed in claim 4, wherein:
the compound represented by Chemical Formula 1 is represented by one of Chemical Formula 3 to Chemical Formula 5,
X³ in Chemical Formula 3 is —O— or —NR^{e}—,
X⁴ in Chemical Formula 4 and X⁵ in Chemical Formula 5 are each independently —CR^{f}—, and
R^{e} and R^{f} are each independently hydrogen, deuterium, or a substituted or unsubstituted C1 to C10 alkyl group.

8. The hardmask composition as claimed in claim 1, wherein the self-polymer has a weight average molecular weight of about 1,000 g/mol to about 200,000 g/mol.

9. The hardmask composition as claimed in claim 1, wherein the self-polymer is included in an amount of about 0.1 wt % to about 30 wt %, based on a total weight of the hardmask composition.

10. The hardmask composition as claimed in claim 1, wherein the solvent includes propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

11. A hardmask layer comprising a cured product of the hardmask composition of claim 1.

12. A method of forming patterns, the method comprising:
providing a material layer on a substrate;
applying the hardmask composition of claim 1 on the material layer;
heat-treating the hardmask composition to form a hardmask layer;
forming a photoresist layer on the hardmask layer;
exposing and developing the photoresist layer to form a photoresist pattern;
selectively removing the hardmask layer using the photoresist pattern to expose a portion of the material layer; and
etching an exposed part of the material layer.

13. The method as claimed in claim 12, wherein forming the hardmask layer includes heat-treating at about 100° C. to about 1,000° C.
